(19) United States
(12) Patent Application Publication
(10) Pub. No.: US 2004/0089891 A1
(43) Pub. Date: May 13, 2004

(54) Semiconductor device including electrode or the like having opening closed and method of manufacturing the same

(75) Inventors: Masatoshi Anma, Tokyo (JP); Masahiko Takeuchi, Tokyo (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: Renesas Technology Corp., TOKYO (JP)

(21) Appl. No.: 10/658,425

(22) Filed: Sep. 10, 2003

(30) Foreign Application Priority Data
Nov. 13, 2002 (JP) 2002-329218

(51) Int. Cl. H01L 27/108; H01L 29/76; H01L 29/94; H01L 31/119

(52) U.S. Cl. 257/296

(57) ABSTRACT

A lower electrode (11) formed of ruthenium has an opening generated by a void at time of formation, for example. A ruthenium oxide film (14) is provided on an upper surface of the lower electrode (11) to close an entry of the opening, and is formed by oxidizing the lower electrode (11). Similarly, a ruthenium oxide film (841) is provided to close an entry of an opening of a plug body (81) formed of ruthenium.

### BACKGROUND OF THE INVENTION

1. Field of the Invention

The present invention relates to a semiconductor device and a method of manufacturing the semiconductor device, and more particularly to a technique for preventing a drawback from being caused by an opening of a lower electrode of a pillar type capacitor or the like, for example, thereby enhancing a reliability of the semiconductor device.

2. Description of the Background Art

A memory device such as a DRAM (Dynamic Random Access Memory) includes a pillar type capacitor, for example. Conventionally, the pillar type capacitor is manufactured in the following manner. First of all, a hole is formed on an interlayer film and a film for a lower electrode of the capacitor is formed by a CVD (Chemical Vapor Deposition) method to fill in the hole, for example. Then, a CMP (Chemical Mechanical Polishing) processing or a dry etching processing is executed such that the film for the lower electrode remains in only the hole, for example. The interlayer film is removed partially or wholly and a film remaining after the processing becomes the lower electrode. A dielectric film and an upper electrode constituting the capacitor to cover the lower electrode are sequentially formed. Thus, the pillar type capacitor is finished.

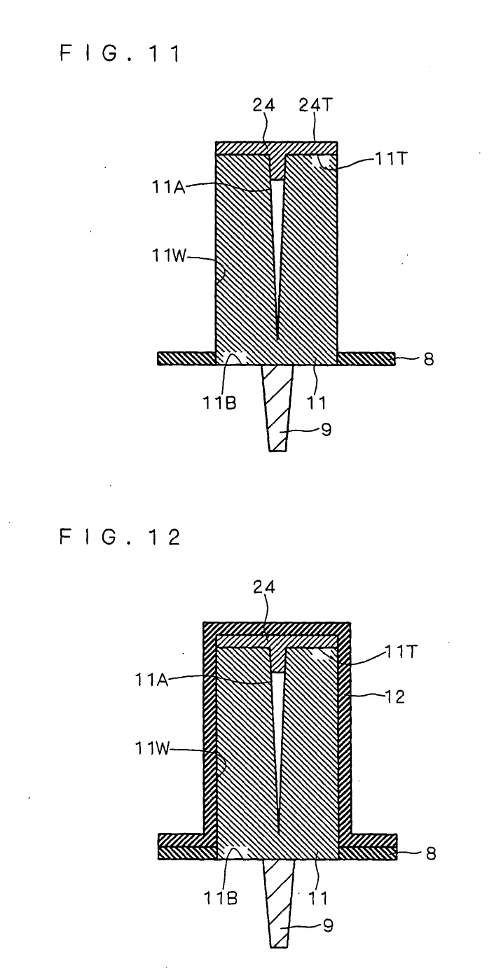

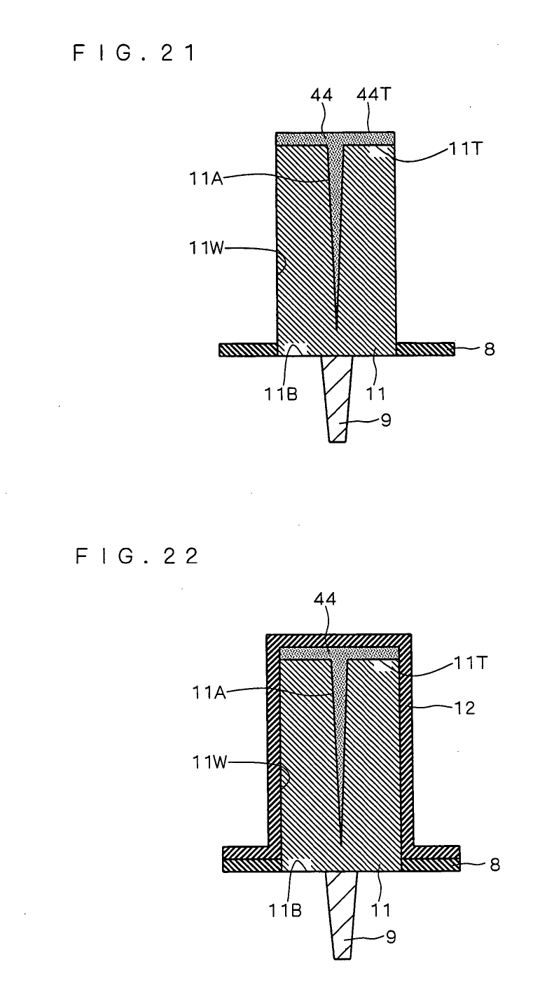

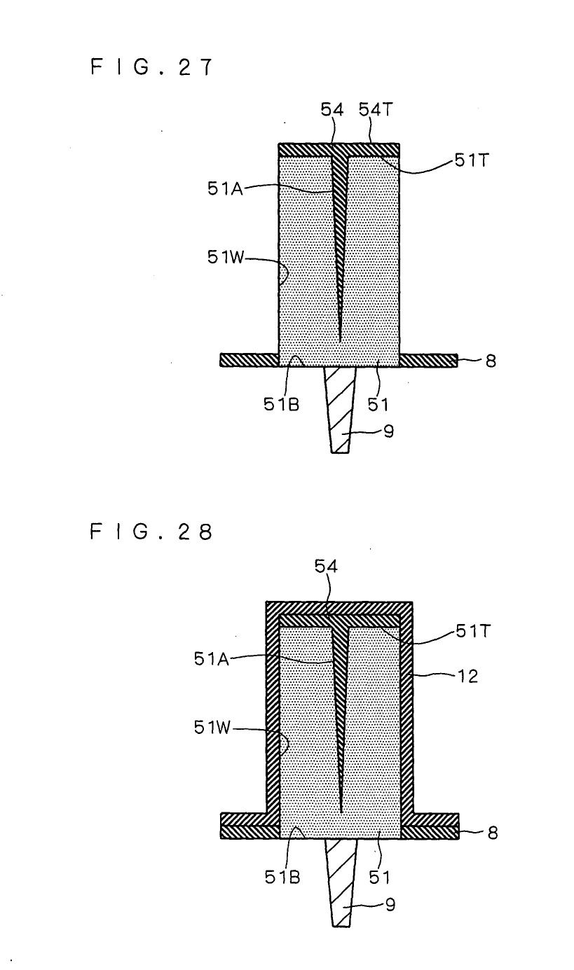

The capacitor of the memory device has been introduced in Japanese Patent Application Laid-Open No. 2000-223671 (FIG. 11), Japanese Patent Application Laid-Open No. 2000-156476 (FIGS. 20 to 30) and Japanese Patent Application Laid

As described above, in a conventional manufacturing method, a film for a lower electrode is buried in a hole of an interlayer film by a CVD method, for example. At this time, an aspect ratio of the hole is increased as film formation progresses (the aspect ratio is grasped to be infinite at the end of the film formation). Therefore, a void is generated in the hole in the film for the lower electrode. The void is generated more easily if an original aspect ratio of the hole is higher. When a subsequent CMP processing or the like is carried out over the film for the lower electrode having the void, the void appears on an exposed surface of the lower electrode to form an opening on the lower electrode. While a dielectric film and an upper electrode of the capacitor are also formed in the opening, it is hard to form these films in sufficient thicknesses in the opening. For this reason, the dielectric film is locally thinned in the opening and a leakage current flows between the upper electrode and the lower electrode through the thin portion. In other words, a charge holding characteristic of the capacitor cannot be obtained. Although the pillar type capacitor has been taken as an example, various problems arise in the case in which a film is generally formed in the opening.

### SUMMARY OF THE INVENTION

In consideration of the above-mentioned respects, it is an object of the present invention to prevent the drawback from being caused by an opening of a lower electrode of a pillar type capacitor, for example, thereby enhancing a reliability of a semiconductor device.

According to a first aspect of the present invention, a semiconductor device includes a lower electrode, an upper electrode and a dielectric film, and furthermore, an electric conductor or an insulator containing a material of the lower electrode as a part of opening on the upper surface. The electric conductor or the insulator is provided at least in the vicinity of an entry in the opening. The dielectric film is provided to face the upper surface and the side surface of the lower electrode, and the upper electrode is provided to face the lower electrode through the dielectric film.

The dielectric film is apt to be thinned in the vicinity of a bottom portion of the opening. However, (the entry of) the opening is closed by the electric conductor or the insulator and the dielectric film does not penetrate into the vicinity of the bottom portion of the opening. Consequently, it is possible to suppress a leakage current caused by the thin dielectric film, and the capacitor can have an excellent charge holding characteristic. As a result, a reliability of the semiconductor device can be enhanced.

According to a second aspect of the present invention, a semiconductor device includes a lower electrode, an upper electrode and a dielectric film, and furthermore, an insulator. The lower electrode has an opening and the insulator is provided in a bottom portion of the opening without completely filling in the opening. The dielectric film is provided on the insulator and the lower electrode without completely filling in the opening, and the upper electrode is provided on the dielectric film.

The dielectric film is apt to be thinned in the vicinity of the bottom portion of the opening. However, since the insulator is provided in the bottom portion, the dielectric film can be prevented from being thinned. Consequently, it is possible to suppress a leakage current caused by the thin dielectric film, and the capacitor can have an excellent charge holding characteristic. As a result, the reliability of the semiconductor device can be enhanced.

According to a third aspect of the present invention, a semiconductor device includes an interlayer film and a plug. The plug has a plug body and an electric interlayer film has a hole. The plug body has an opening on an entry of the hole and is provided in the hole. The electric conductor is provided on an inside and outside of the hole to close the opening of the plug body, and furthermore, is provided so as not to come in contact with the interlayer film.

Since the electric conductor is provided to close the opening of the plug body, it is possible to prevent chemicals or the like from penetrating into the opening to erode the plug body. As a result, the reliability of the semiconductor device can be enhanced.

According to a fourth aspect of the present invention, a method of manufacturing a semiconductor device includes the following steps of (a) to (d). The step (a) is to form an interlayer film and is to open to form a hole. The step (b) is to form a conductive film on the interlayer film to provide the conductive film in the hole. The step (c) is to remove a portion of the conductive film which is provided on an outside of the hole to expose the interlayer film. The step (d) is to oxidize, silicide or nitride an exposed surface of the conductive film to form an oxide film, a silicide film or a nitride film.

Even if the conductive film in the hole has an opening due to a void generated in the formation of the conductive film, for example, (the entry of) the opening can be closed by the oxide film, the silicide film or the nitride film. Consequently, it is possible to prevent chemicals or the like from penetrating into the opening to erode the conductive film. As a result, the reliability of the semiconductor device can be enhanced. Moreover, in the case in which the conductive film in the hole constitutes the lower electrode of the capacitor, for example, it is possible to prevent the dielectric film from penetrating into the vicinity of the bottom portion of the opening by the oxide film or the like. The dielectric film is apt to be thinned in the vicinity of the bottom portion of the dielectric film, and the capacitor can have an excellent charge holding characteristic. As a result, the reliability of the semiconductor device can be enhanced.

According to a fifth aspect of the present invention, a method of manufacturing a semiconductor device having a capacitor includes the following steps of (i) to (p). The step (i) is to form an interlayer film and is to open to form a hole. The step (j) is to form a conductive film along an exposed surface in the hole. The step (k) is to form an insulator on the conductive film to fill in the hole. The step (l) is to remove a portion of the conductive film which is provided on an outside of the hole to expose the interlayer film. Consequently, a lower electrode of the capacitor is formed by the conductive film. The step (m) is to remove the insulator to leave a part of the insulator in a bottom portion of an opening of the lower electrode corresponding to the hole. The step (n) is to remove the interlayer film to expose the lower electrode. The step (o) is to form a dielectric film of the capacitor on the insulator and the lower electrode without completely filling in the opening after the steps (m) and (n). The step (p) is to form an upper electrode of the capacitor on the dielectric film.

The dielectric film is apt to be thinned in the vicinity of the bottom portion of the opening. However, since the insulator is provided in the bottom portion, an aspect ratio of the opening is reduced. Consequently, it is possible to prevent the dielectric film from being thinned. Thus, it is possible to suppress a leakage current caused by the thin dielectric film, and the capacitor can have an excellent charge holding characteristic. As a result, the reliability of the semiconductor device can be enhanced.

These and other objects, features, aspects and advantages of the present invention will become more apparent from the following detailed description of the present invention when taken in conjunction with the accompanying drawings.

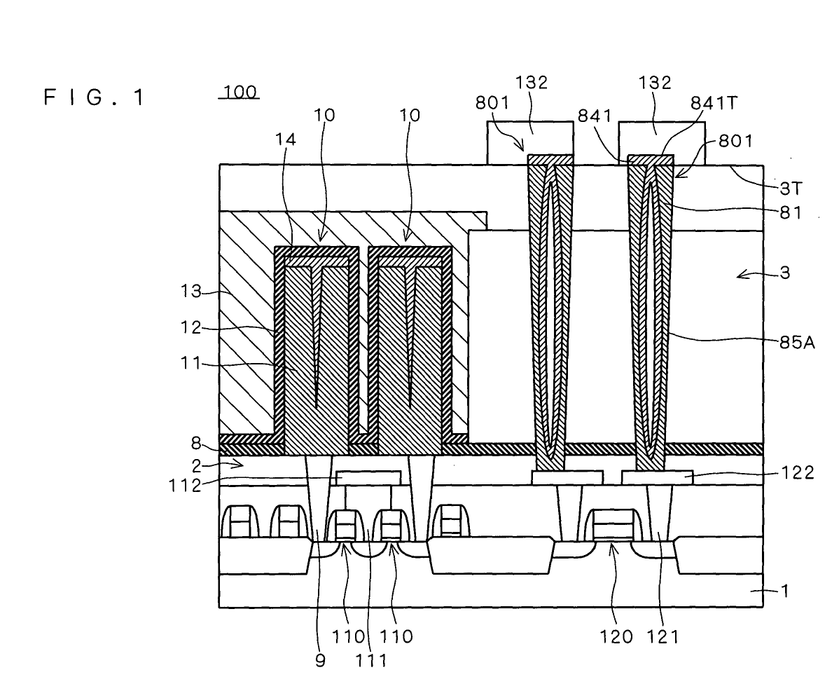

FIG. 1 is a sectional view for explaining a semiconductor device according to first and eighth embodiments,

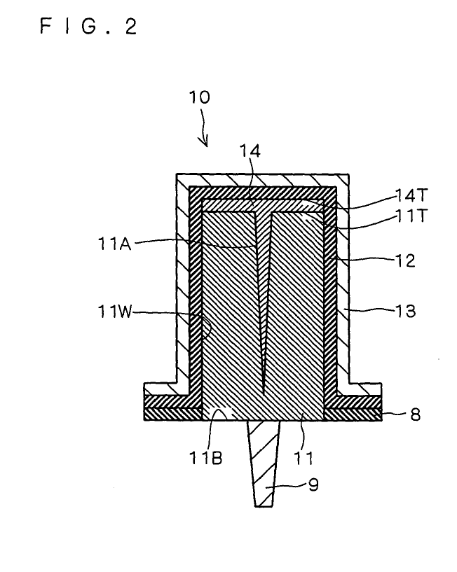

FIG. 2 is a sectional view for explaining a capacitor according to the first embodiment,

FIGS. 3 to 8 are sectional views for explaining a method of manufacturing the capacitor according to the first embodiment,

FIG. 9 is a sectional view for explaining a capacitor according to a second embodiment,

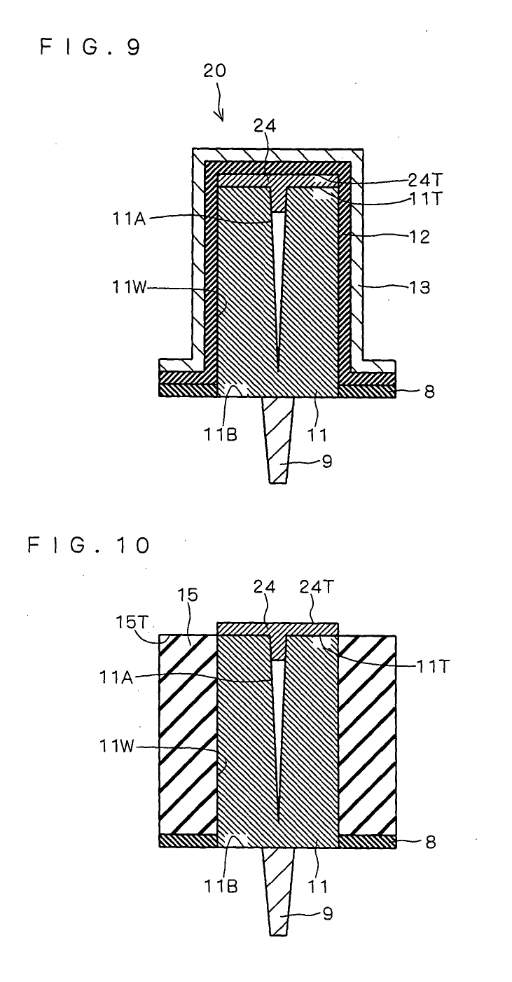

FIGS. 10 to 12 are sectional views for explaining a method of manufacturing the capacitor according to the second embodiment,

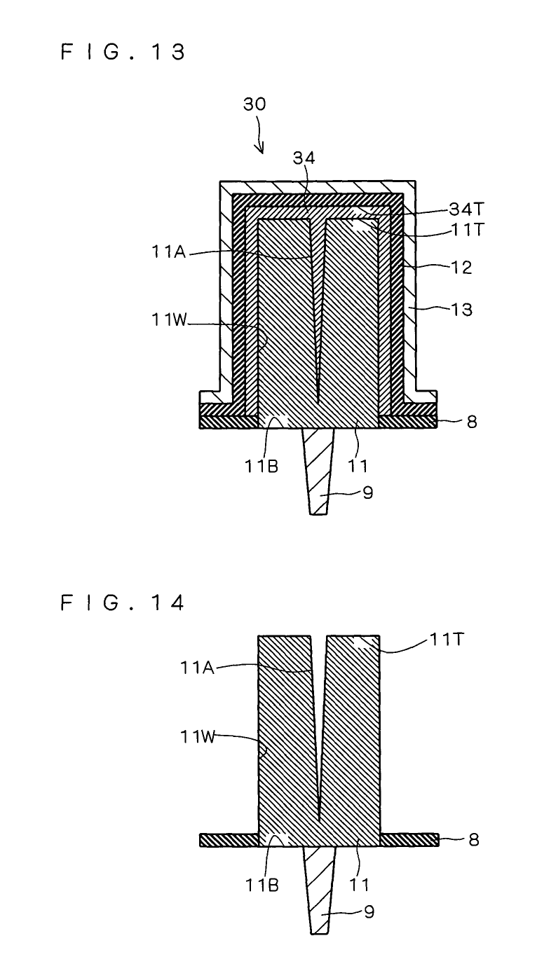

FIG. 13 is a sectional view for explaining a capacitor according to a third embodiment,

FIGS. 14 to 16 are sectional views for explaining a method of manufacturing the capacitor according to the third embodiment,

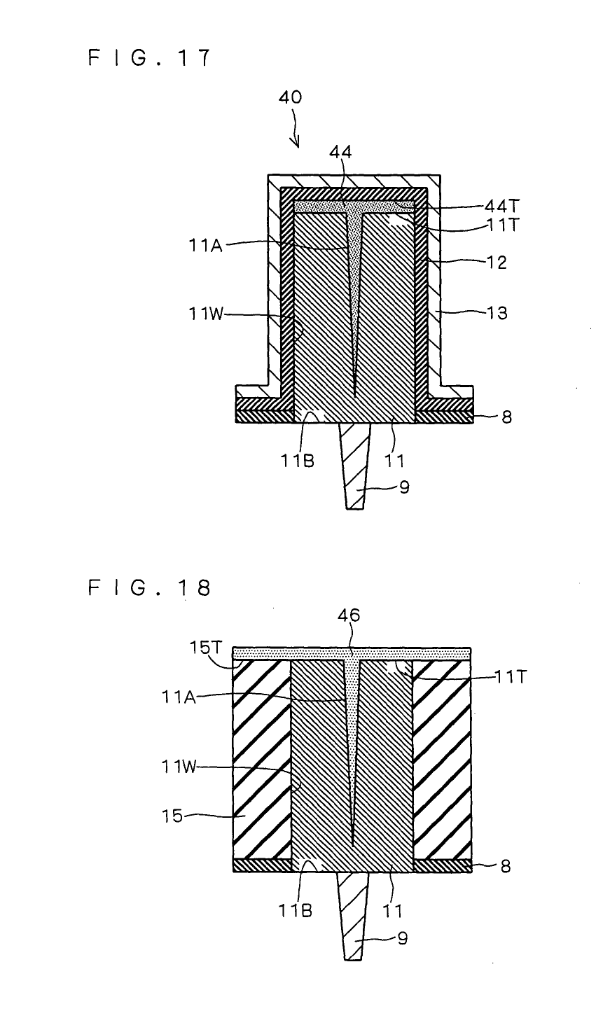

FIG. 17 is a sectional view for explaining a capacitor according to a fourth embodiment,

FIGS. 18 to 22 are sectional views for explaining a method of manufacturing the capacitor according to the fourth embodiment,

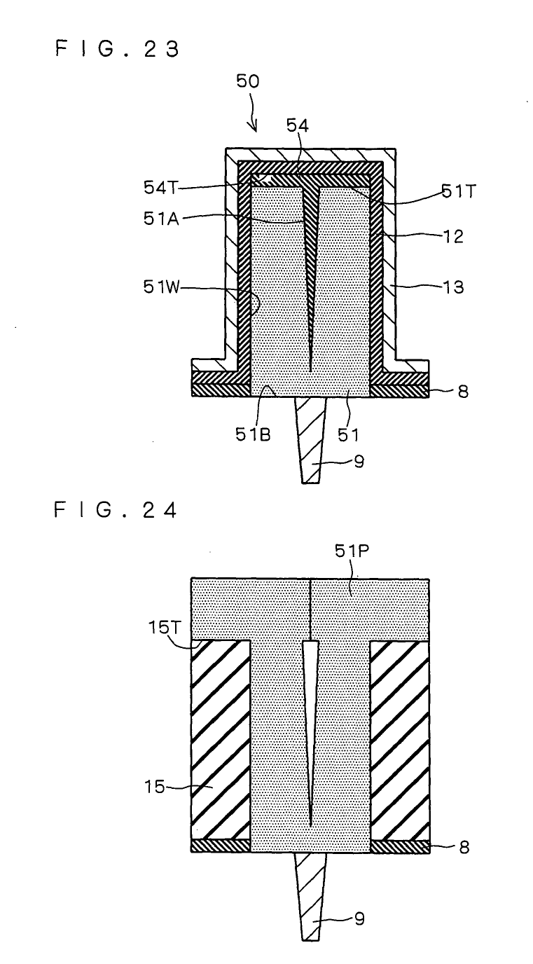

FIG. 23 is a sectional view for explaining a capacitor according to a fifth embodiment,

FIGS. 24 to 28 are sectional views for explaining a method of manufacturing the capacitor according to the fifth embodiment,

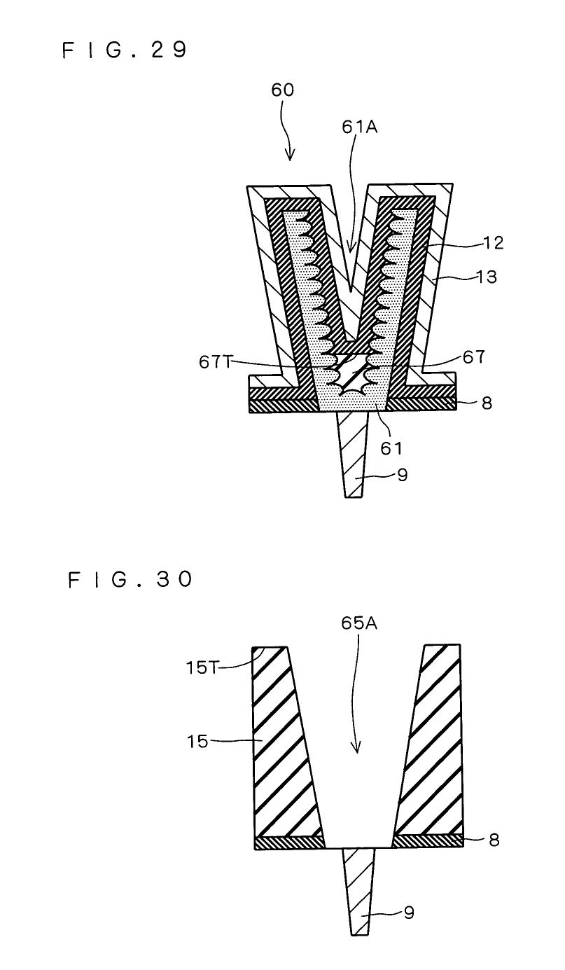

FIG. 29 is a sectional view for explaining a capacitor according to a sixth embodiment, capacitor according to the sixth embodiment,

FIG. 37 is a sectional view for explaining a capacitor according to a seventh embodiment,

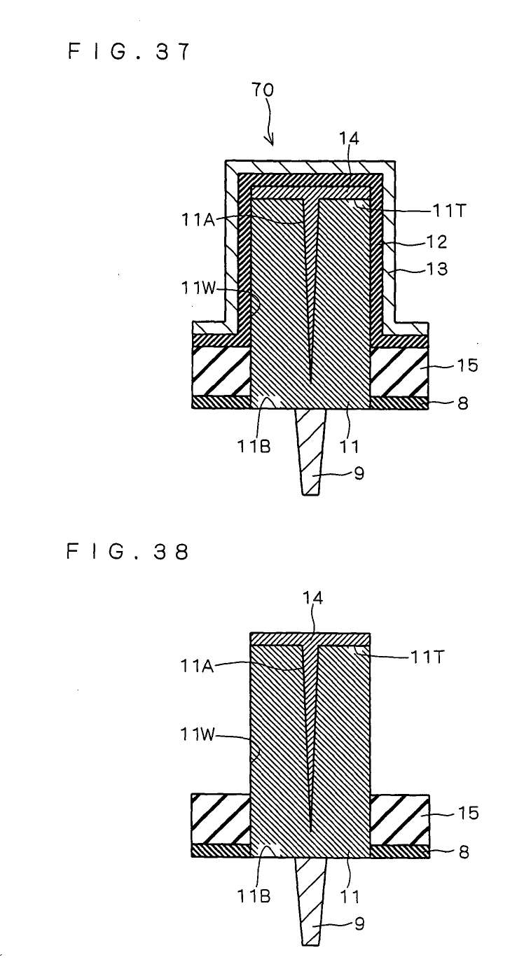

FIG. 38 is a sectional view for explaining a method of manufacturing the capacitor according to the seventh embodiment,

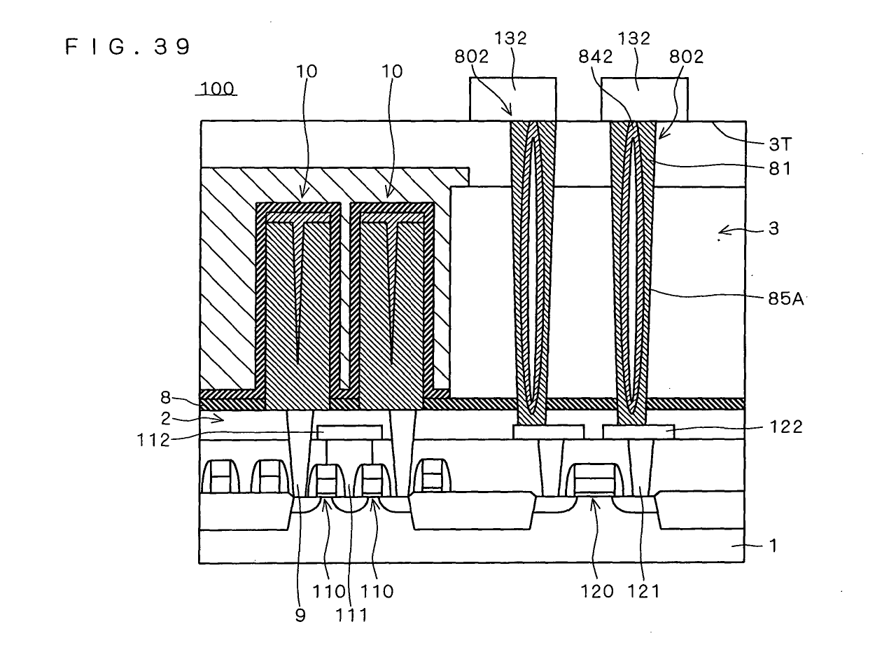

FIG. 39 is a sectional view for explaining another semiconductor device according to an eighth embodiment,

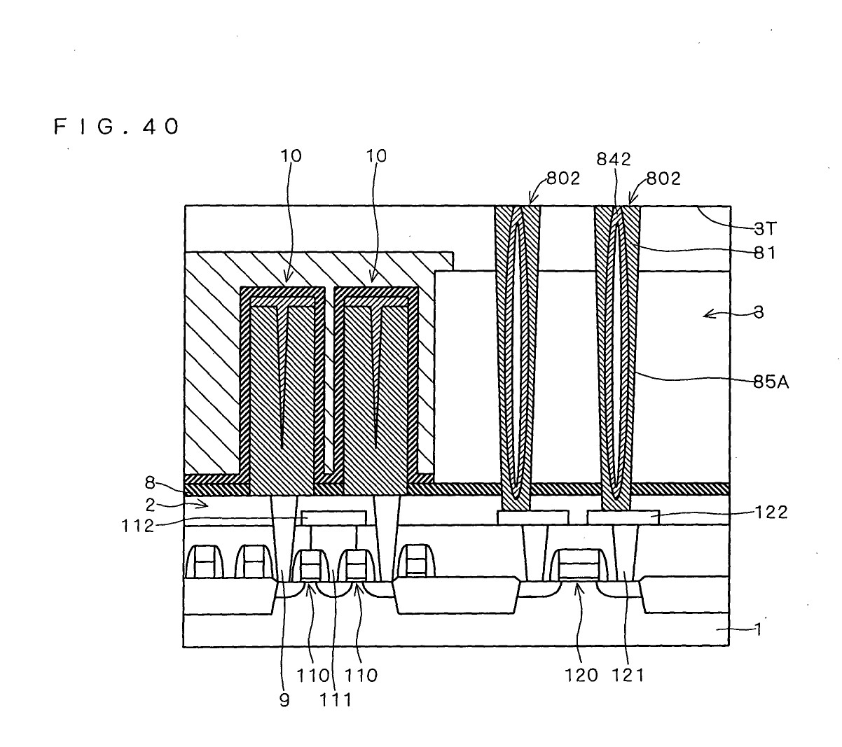

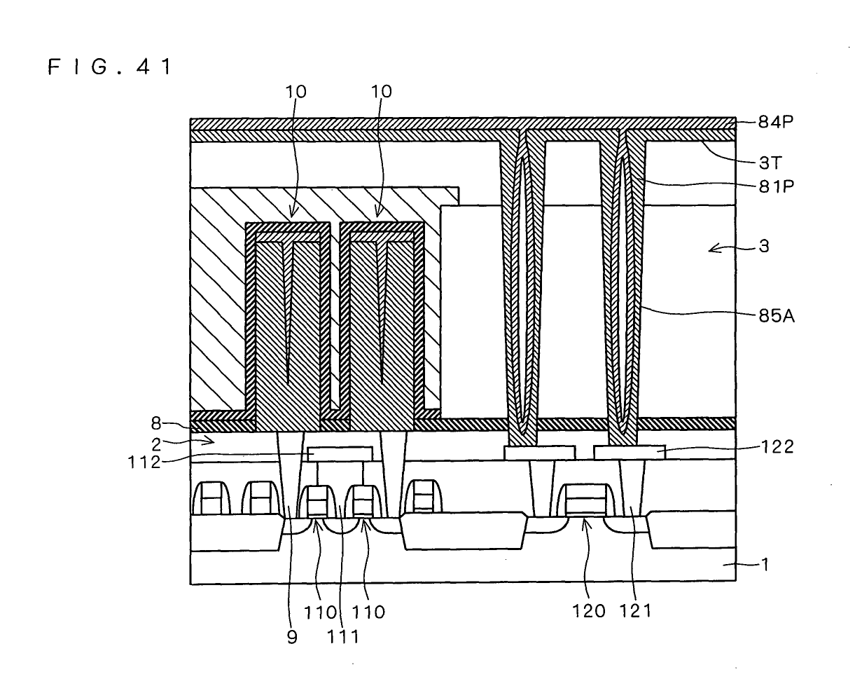

FIGS. 40 and 41 are sectional views for explaining a method of manufacturing another semiconductor device according to the eighth embodiment, and

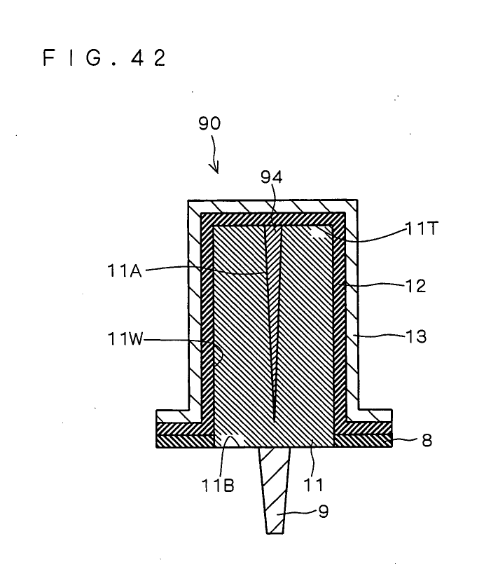

FIG. 42 is a sectional view for explaining a capacitor according to a ninth embodiment.

### DESCRIPTION OF THE PREFERRED EMBODIMENTS

First Embodiment

FIG. 1 is a sectional view for explaining a semiconductor device 100 according to a first embodiment, and FIG. 2 is a sectional view for explaining a capacitor structure or a capacitor 10 according to the first embodiment. FIG. 2 is a partial enlarged view of FIG. 1. While a DRAM (Dynamic Random Access Memory) is illustrated for the semiconductor device 100, application of the capacitor 10 or the like to be described below is not restricted to the DRAM.

As shown in FIG. 1, an MIS (Metal-Insulator-Semiconductor) type transistor 110 for selecting a memory cell of a DRAM is formed in an element formation region of a semiconductor substrate 1 in the semiconductor device 100. One of source/drain regions of the transistor 110 is connected to a wiring (a bit line) 112 through a plug 111 and the other source/drain region is connected to the capacitor 10 through a plug 9. The example, and the elements 110, 111, 112 and 9 are provided in the interlayer film 2.

The capacitor 10 is provided on the interlayer film 2 and is covered with an interlayer film 3 formed by a silicon oxide film, for example. An interlayer film 8 formed by a silicon nitride film, for example, and acting as a stopper film to be described below is provided between the interlayer films 2 and 3. In this case, it is possible to grasp that the capacitor 10 is provided in an “interlayer film” which is a general name of the interlayer films 2, 3 and 8.

FIG. 1 shows the case in which two transistors 110 provided in a single element formation region share the source/drain region and the plug 111 which are connected to the wiring 112, and furthermore, two capacitors 10 connected to the two transistors 110 share a capacitor dielectric film 12 and an upper electrode 13.

An MIS type transistor 120 for a peripheral circuit of the DRAM is formed in another element formation region of the semiconductor substrate 1, for example, and source/drain regions of the transistor 120 are connected to a wiring or an inter-wiring section 122 through a plug 121, respectively. These elements 120, 121 and 122 are covered with the interlayer film 2.

A via hole or a contact hole 85A is provided on the wiring 122 across the interlayer films 2, 8 and 3, and a plug 801 is provided in the via hole 85A. The plug 801 will be described in detail in the following eighth embodiment. A wiring 132 is provided on an upper surface 3T of the interlayer film 3 to come in contact with the plug 801.

With reference to FIG. 2, next, the capacitor 10 will be described. The capacitor 10 is of a stack type, and more specifically, is particularly referred to as a pillar type. The capacitor 10 includes a lower electrode 11, the upper electrode 13, and the electrodes 11 and 13 are formed of ruthenium (Ru) and the dielectric film 12 is formed of tantalum oxide (Ta₂O₅), for example. In particular, the capacitor 10 further includes a ruthenium oxide film (or an electric conductor) 14. The lower electrode will also be referred to as a “storage node electrode” and the upper electrode will also be referred to as a “cell plate electrode”.

The lower electrode 11 takes a shape of a pillar (or column) having an upper surface 11T and a lower surface 11B which are opposed to each other, and a side surface 11W connecting both of the surfaces 11T and 11B, for example. The lower surface 11B of the lower electrode 11 is provided in contact with the interlayer film 2 (see FIG. 1) and the plug 9 in the interlayer film 2. The lower electrode 11 is provided on the interlayer film 2 through an opening (a through hole) of an interlayer film or the stopper film 8 formed on the interlayer film 2 (see FIG. 1). In other words, the stopper film 8 is provided on the interlayer film 2 to surround (to come in contact with) the lower electrode 11 in the vicinity of the lower surface 11B of the lower electrode 11.

The lower electrode 11 has a concave portion or an opening 11A opened on the upper surface 11T. The opening 11A does not reach the lower surface 11B of the lower electrode 11, in other words, does not penetrate through the lower electrode 11. While FIG. 2 shows the case in which a bottom portion of the opening 11A is sharp, the same bottom portion is rounded in some cases.

In particular, the ruthenium oxide film 14 is provided (laminated) on the upper surface 11T of the lower electrode 11 to close an entry of the opening 11A. The ruthenium oxide film 14 is an electric conductor and contains ruthenium to be a material of the lower electrode 11 as a part of a composition. The ruthenium oxide film 14 has such a shape as to cover and plug the opening 11A from the upper surface 11T side of the whole opening 11A as well as the vicinity of the entry of the opening 11A, and furthermore, is extended over the upper surface 11T of the lower electrode 11 successively from the inside of the opening 11A. The ruthenium oxide film 14 is provided in contact with the upper surface 11T of the lower electrode 11 and a surface in the opening 11A. Moreover, an upper surface (a surface opposed to a surface provided in contact with the lower electrode 11) 14T of the ruthenium oxide film 14 has a higher level than that of the upper surface 11T of the lower electrode 11, and more specifically, does not fall into the opening 11A.

As is apparent from a manufacturing method which will be described below, the ruthenium oxide film 14 is provided in contact with the whole upper surface 11T of the lower electrode 11 and has a side surface which continues smoothly to the side surface 11W of the lower electrode 11 (without a step) (In other words, the ruthenium oxide film 14 has the same plane pattern as that of the lower electrode 11). FIG. 2 shows the case in which the opening 11A is completely filled in, and a cavity may be provided in a bottom portion of the opening 11A, for example (see a ruthenium oxide film 24 shown in FIG. 9 which will be described below).

The dielectric film 12 is provided to face the upper surface 11T and the side surface 11W of the lower electrode 11, and furthermore, the upper electrode 13 is provided to face the upper surface 11T and the side surface 11W of the lower electrode 11 through the dielectric film 12. In detail, in the capacitor 10, the dielectric film 12 is extended in contact with the ruthenium oxide film 14, (the side surface 11W of) the lower electrode 11 and the stopper film 8 to cover the lower electrode 11 and the ruthenium oxide film 14 from the upper surface 11T side of the lower electrode 11. The upper electrode 13 is extended on the dielectric film 12 to cover the lower electrode 11 and the oxide film 14 does not fall into the opening 11A. Therefore, the dielectric film 12 and the upper electrode 13 do not penetrate into the opening 11A. Portions of the dielectric film 12 and the upper electrode 13 which are provided on the stopper film 8 have optional sizes, this respect is the same as in a capacitor 20 of FIG. 9 or the like which will be described below.

Next, a method of manufacturing the capacitor 10 will be described with reference to sectional views of FIGS. 3 to 8. First of all, a substrate provided with the elements up to the interlayer film 2 having the plug 9 (see FIG. 1) is prepared. In the substrate in such a condition, an upper surface of the plug 9 is exposed from the interlayer film 2.

As shown in FIG. 3, the stopper film 8 (for example, the silicon nitride film) and an interlayer film 15 (for example, a silicon oxide film) are formed on the interlayer film 2 in this order by a CVD (Chemical Vapor Deposition) method, for example. Since the stopper film 8 also acts as an interlayer film as described above, the films 8 and 15 can be generally referred to as an “interlayer film”.

Next, the interlayer film 15 and the stopper film 8 are opened to form a hole 15A. More specifically, the hole 15A opened on the exposed surface or upper surface 15T of the interlayer film 15 is formed in the interlayer film 15 by a photolithographic technique and a dry etching technique. In this case, the stopper film 8 acts as a stopper film during the dry etching. Subsequently, the stopper film 8 exposed into the hole 15A is removed. Consequently, the hole 15A is caused to reach a surface of the interlayer film 2 (see FIG. 1) and an upper surface of the plug 9 is exposed into the hole 15A.

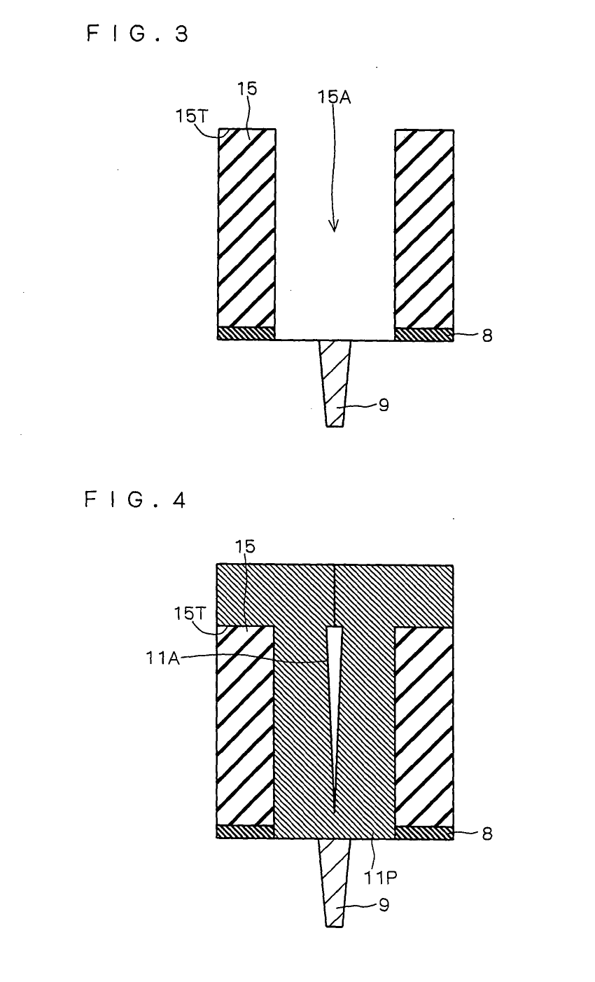

As shown in FIG. 4, then, a ruthenium film (or a conductive film) 11P is formed on the interlayer film 15 to fill in the hole 15A by the CVD method or a PVD (Physical ruthenium film 11P which is provided on the outside of the hole 15A is removed by a CMP (Chemical Mechanical Polishing) method or a dry etch back method, for example, thereby exposing the interlayer film 15. After the removing step, the ruthenium film 11 remaining in the hole 15A becomes the lower electrode 11. In the case in which a plurality of capacitors 10 are to be formed at the same time, the lower electrodes 11 of the capacitors 10 are separated from each other at this removing step.

In the case in which a void is formed in the hole 15A at time of the formation of the ruthenium film 11P (see FIG. 4) and appears on the exposed surface after the step of partially removing the ruthenium film 11P, the void becomes the opening 11A. Although the void in the ruthenium film 11P has a potential for the opening 11A, the opening 11A is not always generated on all the lower electrodes 11 in the semiconductor device 100.

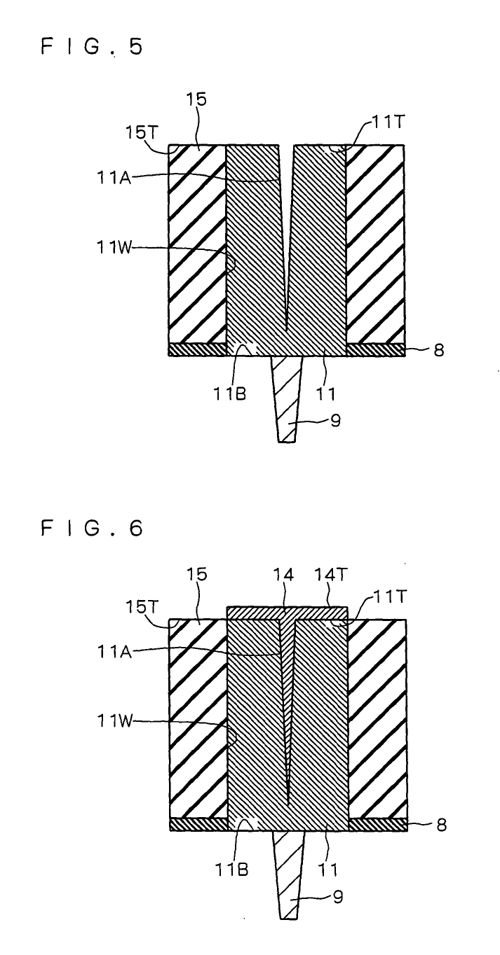

As shown in FIG. 6, next, the exposed surface of the ruthenium film 11, more specifically, the upper surface 11T and an inner surface of the opening 11A are oxidized by a thermal oxidation method (for example, a heat treatment at 550° C. to 800° C. in an oxidizing atmosphere). Consequently, the ruthenium oxide film 14 is formed in contact with the ruthenium film 11. At this time, the opening 11A is filled in by a volume expansion during the formation of the ruthenium oxide film 14 so that the entry of the opening 11A is closed.

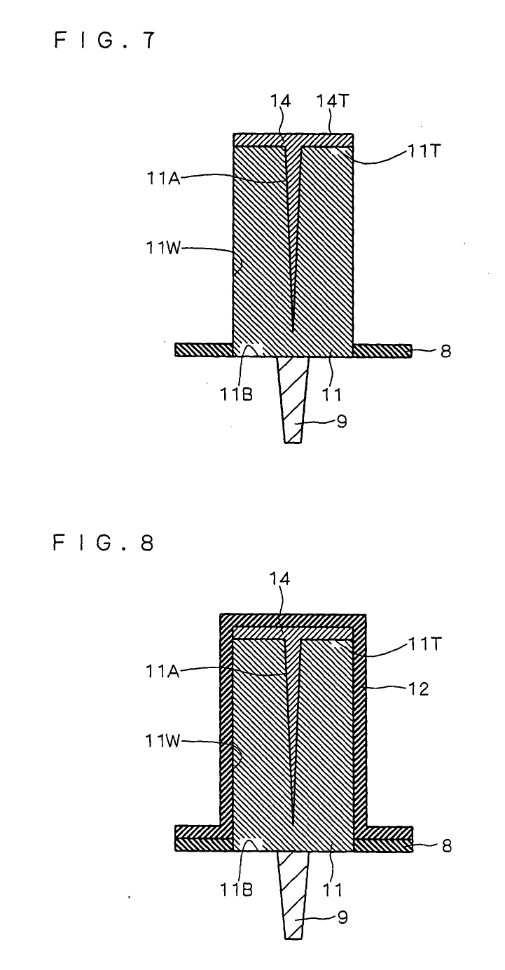

As shown in FIG. 7, then, at least a portion of the interlayer film 15 provided in the vicinity of the ruthenium film 11 is removed by a hydrofluoric acid solution or the like so that the side surface 11W of the ruthenium film 11 is exposed. In this case, the stopper film 8 acts as a stopper film for wet etching. As shown in FIG. 8, thereafter, the dielectric film 12 is formed to cover the ruthenium film 11, that is, the lower electrode 11, Consequently, the capacitor 10 shown in FIG. 2 is obtained. In the case in which the dielectric film 12 and the upper electrode 13 are shared by a plurality of capacitors 10 as shown in FIG. 1, the dielectric film 12 and the upper electrode 13 are simultaneously formed for the capacitors 10.

If the ruthenium oxide film 14 is not provided as in a conventional capacitor, the thin dielectric film 12 is formed in the vicinity of the bottom portion of the opening 11A and a leakage current is generated between the electrodes 11 and 13 due to the thin dielectric film 12. In the capacitor 10, however, (the entry of) the opening 11A is closed by the ruthenium oxide film 14 and the dielectric film 12 and the upper electrode 13 do not penetrate into the vicinity of the bottom portion of the opening 11A. According to the capacitor 10, therefore, it is possible to suppress and prevent such a leakage current. Accordingly, the capacitor 10 has an excellent charge holding characteristic. As a result, a reliability of the semiconductor device 100 is more enhanced than that of a semiconductor device having a conventional capacitor.

In this case, it is supposed that the leakage current can be suppressed if a thickness of the dielectric film in the opening is increased in the conventional capacitor. However, a thickness of the dielectric film provided on the outside of the opening is also increased so that a capacity of the capacitor is reduced. On the other hand, according to the capacitor 10, it is not necessary to increase the thickness of the dielectric film 12 as a countermeasure against the leakage current. For this reason, such a reduction in the capacity is not caused.

Japanese Patent Application Laid-Open No. 2000-223671 has introduced a technique for forming a ruthenium film over a whole surface by a sputtering method or a CVD method, for example, and patterning the same film by using a photolithographic however, an opening cannot be generated on the ruthenium film. There has been described a technique for forming a silicon oxide film, for example, on the ruthenium film and then patterning both of the films. However, the silicon oxide film does not close an opening of the ruthenium film, since the ruthenium film has no opening as described above. The silicon oxide film does not contain ruthenium in a part of a composition. As described in a paragraph [0168] of the same document, moreover, it is possible to form a lower electrode by a multilayered film having a ruthenium film and a ruthenium oxide film. In the same paragraph, a method of forming the ruthenium oxide film by oxidation of the ruthenium film has not been introduced.

Second Embodiment

FIG. 9 is a sectional view for explaining a capacitor 20 according to a second embodiment. The capacitor 20 can be applied to the semiconductor device 100 in FIG. 1 in place of the capacitor 10.

The capacitor 20 has a structure in which the ruthenium oxide film 14 of the capacitor 10 in FIG. 2 is replaced with a ruthenium oxide film 24, and other structures of the capacitor 20 are basically the same as those of the capacitor 10 in FIG. 2. As shown in FIG. 9, the ruthenium oxide film 24 has such a shape that the ruthenium oxide film 14 in FIG. 2 does not reach the vicinity of a bottom portion of an opening 11A and the opening 11A is not completely filled in. An upper surface 24T of the ruthenium oxide film 24 corresponds to the upper surface 14T of the ruthenium oxide film 14 (see FIG. 2).

Next, a method of manufacturing the capacitor 20 will be described with reference to sectional views of FIGS. 10 to 12. First of all, a substrate in the state of FIG. 5 is obtained by using the method of manufacturing the capacitor 10, for example.

As shown in FIG. 10, then, an exposed surface of the ruthenium film 11 is Consequently, the ruthenium oxide film 24 is formed in contact with a ruthenium film 11 so that an entry of the opening 11A is closed.

Thereafter, an interlayer film 15 is removed (see FIG. 11), a dielectric film 12 is formed (see FIG. 12) and an upper electrode 13 is formed by using the method of manufacturing the capacitor 10, for example. Consequently, the capacitor 20 in FIG. 9 is obtained.

By the ruthenium oxide film 24, the capacitor 20 can produce the same effects as those of the capacitor 10. Furthermore, the plasma oxidization is a lower temperature process than thermal oxidation to be used in the method of manufacturing the capacitor 10. According to the capacitor 20, therefore, it is possible to suppress a change in a profile of impurity layers (source/drain regions of transistors 110 and 120 and the like) which have already been formed, for example. Thus, a reliability of the semiconductor device 100 can be enhanced.

Third Embodiment

FIG. 13 is a sectional view for explaining a capacitor 30 according to a third embodiment. In place of the capacitor 10, the capacitor 30 can be applied to the semiconductor device 100 in FIG. 1.

The capacitor 30 has a structure in which the ruthenium oxide film 14 of the capacitor 10 in FIG. 2 is replaced with a ruthenium oxide film 34, and other structures of the capacitor 30 are basically the same as those of the capacitor 10 in FIG. 2.

As shown in FIG. 13, the ruthenium oxide film 34 includes a portion having the same shape as that of the ruthenium oxide film 14 in FIG. 2 and a portion provided on a side surface 11W of a lower electrode 11 (in contact with the side surface 11W). Both of these portions are coupled to each other. Accordingly, the ruthenium oxide film 34 is from an upper surface 11T of the lower electrode 11. The ruthenium oxide film 34 has an upper surface 34T corresponding to the upper surface 14T of the ruthenium oxide film 14 (see FIG. 2). An end of the portion in the ruthenium oxide film 34 which is provided on the side surface 11W is formed in contact with a stopper film 8.

Due to a difference in a shape between the ruthenium oxide films 14 and 34, a dielectric film 12 is extended in contact with the ruthenium oxide film 34 and the stopper film 8 in the capacitor 30. At this time, the dielectric film 12 does not come in contact with the lower electrode 11 but faces the upper surface 11T and the side surface 11W of the lower electrode 11 through the ruthenium oxide film 34. Moreover, an upper electrode 13 faces the lower electrode 11 through the dielectric film 12 and the ruthenium oxide film 34.

Next, a method of manufacturing the capacitor 30 will be described with reference to sectional views of FIGS. 14 to 16. First of all, a substrate in the state of FIG. 5 is obtained by using the method of manufacturing the capacitor 10, for example.

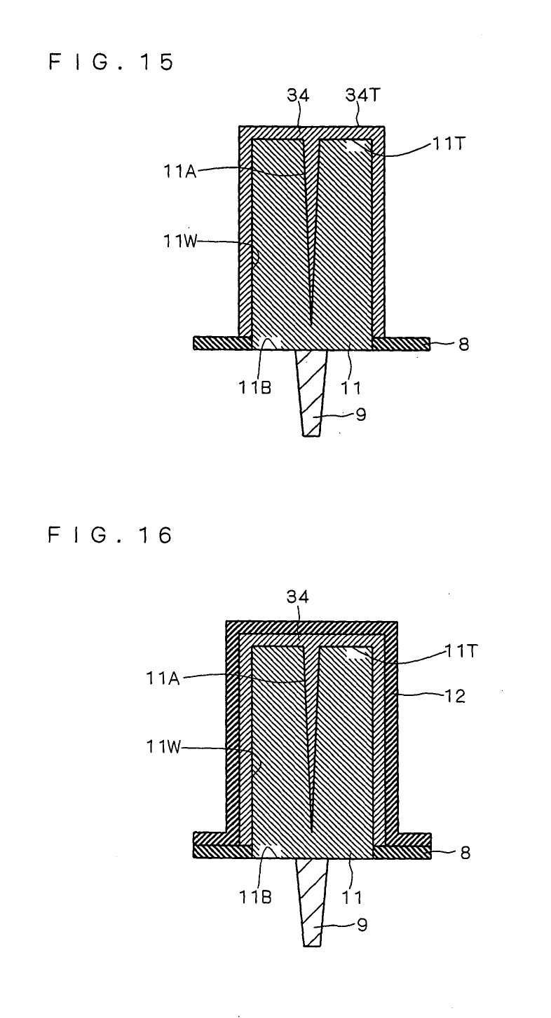

While the step of forming the ruthenium oxide film 14 and the step of removing the interlayer film 15 are executed in this order in the method of manufacturing the capacitor 10 described above, these steps are carried out in reverse order in the method of manufacturing the capacitor 30. In other words, the interlayer film 15 is removed before formation of the ruthenium oxide film 34. More specifically, at least a portion of the interlayer film 15 provided in the vicinity of the ruthenium film 11 is removed to expose the side surface 11W of the ruthenium film 11 as shown in FIG. 14. As shown in FIG. 15, then, the exposed surface of the ruthenium film 11, that is, the upper surface 11T, the side surface 11W and an inner surface of an opening 11A are oxidized by thermal oxidation, for example, as shown in FIG. 15. Consequently, the ruthenium oxide film 34 is formed ruthenium oxide film 34 and an entry of the opening 11A is closed.

Then, the dielectric film 12 is formed (see FIG. 16) and the upper electrode 13 is formed by using the method of manufacturing the capacitor 10, for example. Consequently, the capacitor 30 in FIG. 13 is obtained.

By the ruthenium oxide film 34, the capacitor 30 can produce the same effects as those of the capacitor 10, and furthermore, the following effects can also be obtained. While a portion of the dielectric film 12 which is formed between both of the electrodes 11 and 13 is provided in contact with both of the lower electrode 11 which is formed of ruthenium and the ruthenium oxide film 14 in the capacitor 10 of FIG. 2, it is provided in contact with only the ruthenium oxide film 34 in the capacitor 30. According to the capacitor 30, therefore, the dielectric film 12 is formed on a single foundation. In the case in which a crystalline material is to be used as the dielectric film 12, for example, the dielectric film 12 can be therefore formed homogeneously (such that a characteristic is not locally changed). As a result, a reliability of the semiconductor device 100 can be enhanced.

Depending on which is more preferable for the foundation, ruthenium oxide or ruthenium, that is, which has a larger surface, the ruthenium oxide or the ruthenium, it is also possible to select the capacitors 10 and 30, a capacitor 90 shown in FIG. 42 which will be described below, and the like.

While the thermal oxidation has been used for the formation of the ruthenium oxide film 34 in the above description, it is also possible to use plasma oxidation.

Fourth Embodiment

FIG. 17 is a sectional view for explaining a capacitor 40 according to a fourth embodiment. The capacitor 40 can be applied to the semiconductor device 100 in FIG. 1

The capacitor 40 has a structure in which the ruthenium oxide film 14 of the capacitor 10 in FIG. 2 is replaced with a ruthenium silicide film 44 and other structures of the capacitor 40 are basically the same as those of the capacitor 10 in FIG. 2. The ruthenium silicide film 44 has an upper surface 44T corresponding to the upper surface 14T of the ruthenium oxide film 14 (see FIG. 2). While FIG. 17 shows the case in which the ruthenium silicide film 44 has the same shape as that of the ruthenium oxide film 14 in FIG. 2, the ruthenium silicide film 44 does not need to reach the vicinity of a bottom portion of an opening 11A in the same manner as the ruthenium oxide film 24 in FIG. 9.

Next, a method of manufacturing the capacitor 40 will be described with reference to sectional views of FIGS. 18 to 22. First of all, a substrate in the state of FIG. 5 is obtained by using the method of manufacturing the capacitor 10, for example.

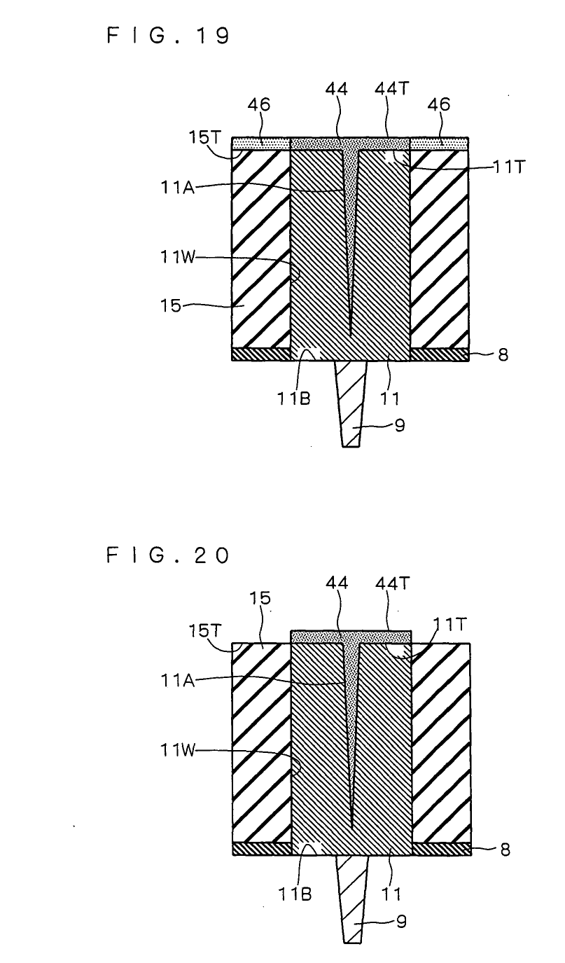

As shown in FIG. 18, then, a silicon film 46 is formed on an exposed surface of a ruthenium film 11 and an exposed surface of an interlayer film 15 by a CVD method or a PVD method, for example. In this case, the silicon film 46 is also deposited in the opening 11A. As shown in FIG. 19, next, the silicon film 46 is caused to react to the ruthenium film 11 to form a ruthenium silicide film 44. The opening 11A is closed by the ruthenium silicide film 44. At this time, when the silicon film 46 is formed at least in the vicinity of an entry of the opening 11A, the opening 11A is closed by the ruthenium silicide film 44. Moreover, the unreacted silicon film 46 may remain in the vicinity of a bottom portion of the opening 11A. By utilizing a silicide reaction, the ruthenium silicide film 44 is formed in the same plane pattern as that of a lower electrode 11.

As shown in FIG. 20, thereafter, the silicon film 46 remaining without the silicide reaction (see FIG. 19) is removed by a dry etching method or a chemical treatment, for example. 12 is formed (see FIG. 22) and an upper electrode 13 is formed by using the method of manufacturing the capacitor 10, for example. Consequently, a capacitor 40 shown in FIG. 17 is obtained.

By the silicide ruthenium film 44, the capacitor 40 can produce the same effects as those of the capacitor 10. By patterning the unreacted silicon film 46, it is possible to form a wiring, a fuse or a resistor by the silicon film 46, for example. In other words, the steps of forming and removing the silicon film 46 can be shared by the step of forming the wiring or the like and the step of forming the silicide ruthenium film 44.

In the same manner as the capacitor 30, the silicon film 46 may be formed to silicide the lower electrode 11 after a side surface 11W of the lower electrode 11 is exposed.

Fifth Embodiment

FIG. 23 is a sectional view for explaining a capacitor 50 according to a fifth embodiment. The capacitor 50 can be applied to the semiconductor device 100 in FIG. 1 in place of the capacitor 10.

The capacitor 50 has a structure in which the lower electrode 11 and the ruthenium oxide film 14 in the capacitor 10 of FIG. 2 are replaced with a lower electrode 51 and a silicon nitride film (or an insulator) 54 respectively, and other structures of the capacitor 50 are basically the same as those of the capacitor 10 in FIG. 2.

In detail, the lower electrode 51 in FIG. 23 is formed of silicon and has the same shape as that of the lower electrode 11 in FIG. 2. The lower electrode 51 has an upper surface 51T, a lower surface 51B, a side surface 51W and an opening 51A corresponding to the upper surface 11T, the lower surface 11B, the side surface 11W and the opening 11A of the lower electrode 11 in FIG. 2. Moreover, a silicon nitride film 54 in FIG. 23 surface 54T corresponding to the upper surface 14T of the ruthenium oxide film 14. The silicon nitride film 54 does not need to reach the vicinity of a bottom potion of the opening 51A in the same manner as the ruthenium oxide film 24 in FIG. 9.

Next, a method of manufacturing the capacitor 50 will be described with reference to sectional views of FIGS. 24 to 28. First of all, a substrate in the state of FIG. 3 is obtained by using the method of manufacturing the capacitor 10, for example.

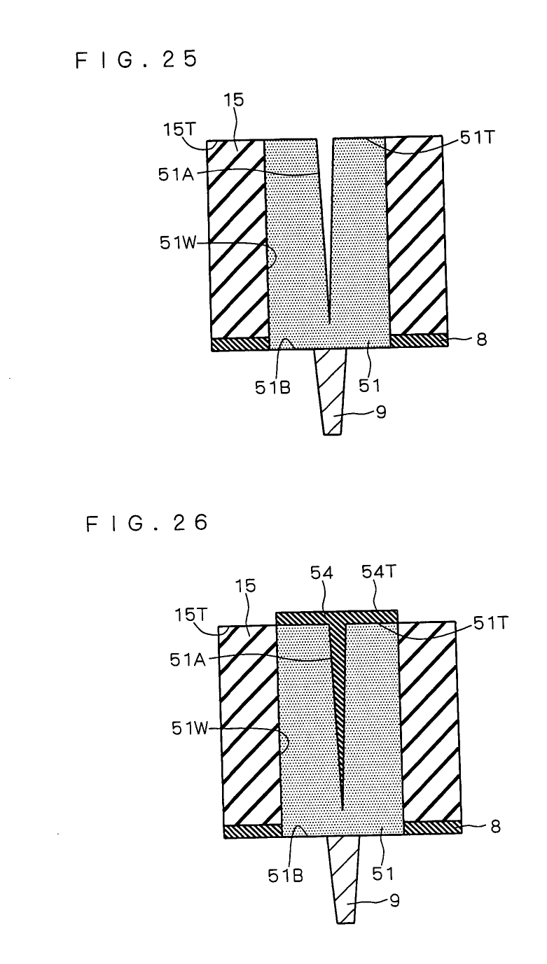

As shown in FIG. 24, then, a silicon film (or a conductive film) 51P is formed on an interlayer film 15 to fill in a hole 15A by a CVD method, for example. As shown in FIG. 25, thereafter, a portion of the silicon film 51P which is provided on the outside of the hole 15A is removed by a CMP method or a dry etch back method, for example. After the removing step, the silicon film 51 remaining in the hole 15A becomes the lower electrode 51. In the case in which a plurality of capacitors 50 are to be formed at the same time, the lower electrodes 51 of the capacitors 50 are separated from each other at this removing step.

At this time, in the same manner as in the method of manufacturing the capacitor 10 or the like, a void in the silicon film 51P has a potential for the opening 51A, the opening 51A is not generated on all the lower electrodes 51 in the semiconductor device 100.

As shown in FIG. 26, next, the exposed surface of the silicon film 51, more specifically, the upper surface 51T and an inner surface of the opening 51A are nitrided by thermal nitriding (for example, a heat treatment at 750° C. to 950° C. in a nitriding atmosphere). Consequently, the silicon nitride film 54 is formed in contact with the silicon film 51. At this time, the opening 51A is filled in by a volume expansion during the formation of the silicon nitride film 54 so that an entry of the opening 51A is closed. formed (see FIG. 28) and an upper electrode 13 is formed by using the method of manufacturing the capacitor 10, for example. Consequently, the capacitor 50 in FIG. 23 is obtained.

By the silicon nitride film 54, the capacitor 50 can produce the same effects as those of the capacitor 10.

While the thermal nitriding method has been used for forming the silicon nitride film 54 in the above description, a plasma nitriding method can also be used. The plasma nitriding method is a lower temperature process than a thermal nitriding method. In the same manner as in the capacitor 20, therefore, it is possible to suppress a change in a profile of an impurity layer which has already been formed. Thus, a reliability of the semiconductor device 100 can be enhanced. By using an oxidizing method or a silicide reaction, it is also possible to apply a silicon oxide film or a silicide film in place of the silicon nitride film 54.

Sixth Embodiment

FIG. 29 is a sectional view for explaining a capacitor 60 according to a sixth embodiment. The capacitor 60 can be applied to the semiconductor device 100 in FIG. 1 in place of the capacitor 10.

As shown in FIG. 29, the capacitor 60 is of a stack type, and more specifically, is particularly referred to as a crown type or a cylinder type. The capacitor 60 includes a lower electrode 61, an upper electrode 13, and a capacitor dielectric film 12 provided between both of the electrodes 61 and 13, and furthermore, an insulator 67 formed of silicon oxide, for example.

The lower electrode 61 is formed of silicon, for example, and is of the cylinder shape or a vessel shape. Description will be given to the case in which a concave narrowed from an entry toward a bottom portion. An inner surface of the lower electrode 61, that is, an inner surface of the opening 61A is roughened. In the same manner as the lower electrode 11 in FIG. 2, the lower electrode 61 is provided on the interlayer film 2 (see FIG. 1) and a bottom portion of the lower electrode 61 is provided in contact with a plug 9 in the interlayer film 2.

The insulator 67 formed of silicon oxide, for example, is provided on a bottom portion in the opening 61A of the lower electrode 61. The insulator 67 is provided without completely filling in the opening 61A. More specifically, an upper surface (a surface on the entry side of the opening 61A) 67T of the insulator 67 does not reach a level of the entry of the opening 61A.

The dielectric film 12 is provided to face and cover the lower electrode 61 and the insulator 67, and furthermore, the upper electrode 13 is provided to face the lower electrode 61 through the dielectric film 12 and to cover the elements 12, 61. More specifically, in the capacitor 60, the dielectric film 12 is extended in contact with the lower electrode 61, the insulator 67 and a stopper film 8 and covers the lower electrode 61 and the insulator 67. Moreover, the upper electrode 13 is extended in contact with the dielectric film 12 to cover the lower electrode 61 and the insulator 67. At this time, the dielectric film 12 is extended along surfaces of the lower electrode 61, the insulator 67 and the stopper film 8 and enters the opening 61A. However, the dielectric film 12 does not completely fill in the opening 61A. For this reason, the upper electrode 13 is also extended in the opening 61A. More specifically, the dielectric film 12 and the upper electrode 13 face the roughened surface of the lower electrode 61 in the capacitor 60.

Next, a method of manufacturing the capacitor 60 will be described with reference to sectional views of FIGS. 30 to 36. First of all, a substrate provided with the substrate in such a condition, an upper surface of the plug 9 is exposed from the interlayer film 2.

In the same manner as in the method of manufacturing the capacitor 10 described above, the stopper film 8 and an interlayer film 15 are formed on the interlayer film 2 in this order and the interlayer film 15 and the stopper film 8 are then opened sequentially to form a hole 65A as shown in FIG. 30. Consequently, the upper surface of the plug 9 is exposed into the hole 65A. In particular, the hole 65A is formed to be gradually narrowed from an upper surface 15T of the interlayer film 15 toward the stopper film 8 and the plug 9.

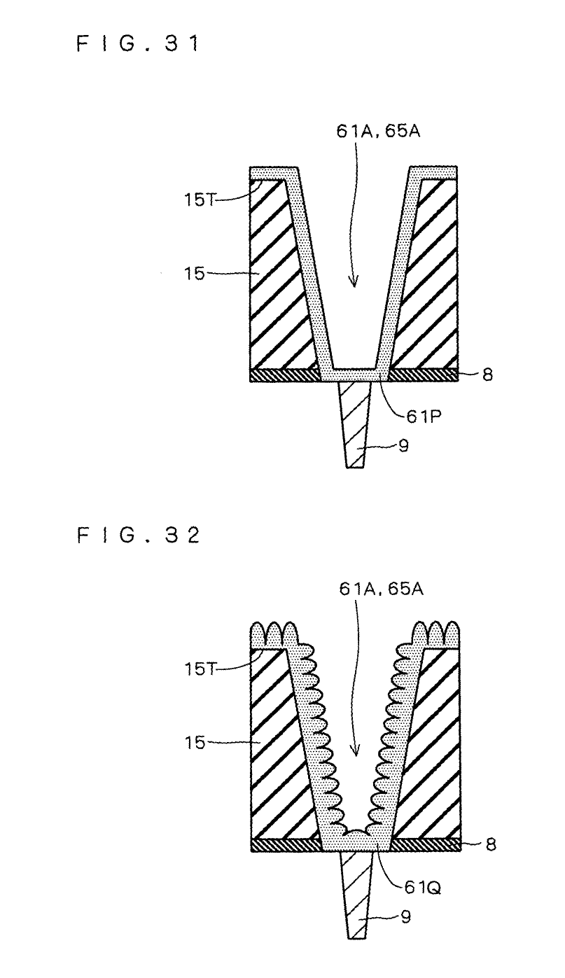

As shown in FIG. 31, then, an amorphous silicon film (or a conductive film) 61P is formed on the upper surface 15T of the interlayer film 15 and an inner surface of the hole 65A by a CVD method, for example. At this time, the silicon film 61P is formed along the exposed surface in the hole 65A so as not to completely fill in the hole 65A. Consequently, the vessel shape is configured by a portion of the silicon film 61P which is provided in the hole 65A (which is formed to be the lower electrode 61 later). As shown in FIG. 32, thereafter, the exposed surface of the silicon film 61P is roughened to obtain a silicon film 61Q. More specifically, a crystal growth nucleus is formed on the silicon film 61P by a gas containing silicon, for example, a disilane (Si₂H₆) gas and a heat treatment is subsequently executed at 750° C. to 850° C. to migrate the silicon.

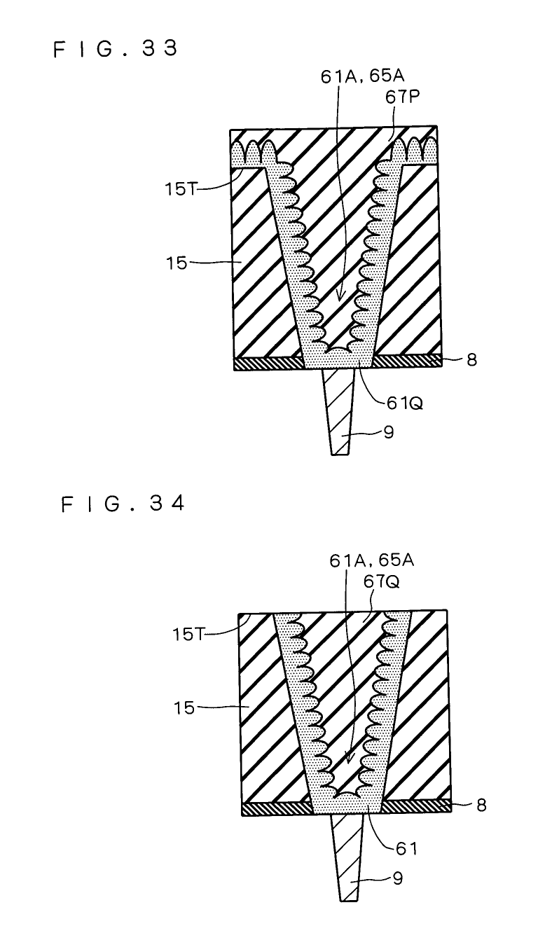

As shown in FIG. 33, next, an insulator (for example, a silicon oxide film) 67P is formed on the silicon film 61Q by a CVD method or a spin coating method, thereby filling in the hole 65A. As shown in FIG. 34, then, portions of the silicon film 61Q and the insulator 67P which are provided on the outside of the hole 65A are removed by a CMP method, for example, to expose the interlayer film 15. Consequently, the silicon and the lower electrode 61 has an opening 61A corresponding to the hole 65A. Moreover, a part of the insulator 67P remains as an insulator 67Q in the opening 61A. In the case in which a plurality of capacitors 60 are to be formed at the same time, the lower electrodes 61 of the capacitors 60 are separated from each other at this removing step.

As shown in FIG. 35, thereafter, the interlayer film 15 and the insulator 67Q are removed by a hydrofluoric acid solution or the like. In particular, the insulator 67Q is removed such that a part thereof remains as the insulator 67 in the bottom portion of the opening 61A. Moreover, at least a portion of the interlayer film 15 which is provided in the vicinity of the lower electrode 61 is removed to expose an outer surface of the lower electrode 61. At this time, since both of the interlayer film 15 and the insulator 67Q are formed by a silicon oxide film, both of the elements 15 and 67Q can be removed collectively. In other words, the interlayer film 15 and the insulator 67Q may be formed by different materials. In such a case, the elements 15 and 67Q may be sequentially removed (in any order).

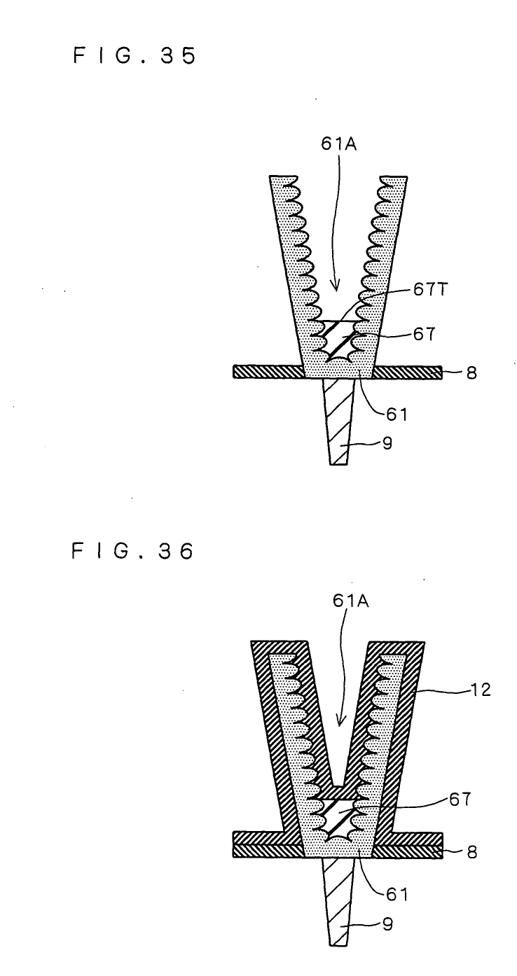

As shown in FIG. 36, then, the dielectric film 12 is formed to cover the lower electrode 61 and the insulator 67. In this case, the dielectric film 12 is formed on the insulator 67 and the lower electrode 61 so as not to completely fill in the opening 61A. Thereafter, the upper electrode 13 is formed on the dielectric film 12. Thus, the capacitor 60 shown in FIG. 29 is obtained.

If the insulator 67 is not provided, the thin dielectric film 12 is formed in the vicinity of the bottom portion of the opening 61A so that a leakage current is generated between the electrodes 61 and 13 due to the thin dielectric film 12. In the capacitor 60, however, the insulator 67 is provided on the bottom portion of the opening 61A 12 and the upper electrode 13 do not penetrate into the vicinity of the bottom portion of the opening 61A. According to the capacitor 60, thus, it is possible to suppress and prevent such a leakage current. Accordingly, the capacitor 60 has an excellent charge holding characteristic. As a result, the semiconductor device 100 has a high reliability.

Such an advantage can be obtained also in the case in which the opening 61A has almost the same size from the entry to the bottom portion and/or the case in which the inner surface of the opening 61A is not roughened. In the case in which the opening 61A is gradually narrowed from the entry toward the bottom portion and/or the case in which the inner surface of the opening 61A is roughened, the dielectric film 12 is apt to be thinned, consequently, the above-mentioned effects can be exhibited remarkably.

Japanese Patent Application Laid-Open No. 2000-156476 has introduced a capacitor having a lower electrode of a cylinder type. In this capacitor, an insulator other than a capacitor dielectric film is not provided in a cylinder.

Seventh Embodiment

FIG. 37 is a sectional view for explaining a capacitor 70 according to a seventh embodiment. Moreover, FIG. 38 is a sectional view for explaining a method of manufacturing the capacitor 70. The capacitor 70 can be applied to the semiconductor device 100 in FIG. 1 in place of the capacitor 10.

In the method of manufacturing the capacitor 10 described above, the interlayer film 15 provided around the lower electrode 11 is removed such that the stopper film 8 is exposed, that is, is wholly removed in a vertical direction, as shown in FIGS. 6 and 7.

On the other hand, the interlayer film 15 is caused to partially remain as shown in FIG. 38 in the method of manufacturing the capacitor 70. In the same manner as in the method of manufacturing the capacitor 10, then, a dielectric film 12 and an upper obtained. By such a manufacturing method, the dielectric film 12 of the capacitor 70 is provided in contact with the remaining interlayer film 15, not the stopper film 8.

Consequently, the lower electrode 11 can be supported by the remaining interlayer film 15. Therefore, it is possible to prevent the lower electrode 11 from falling down or being broken. More specifically, if a height of the lower electrode 11 is excessively great with respect to a strength of a material constituting the lower electrode 11, the lower electrode 11 is apt to fall down or be broken. According to the manufacturing method described above, however, such a situation can be avoided. Furthermore, an amount (a thickness) of an insulating film provided between the dielectric film 12 and a plug 9 is increased by the remaining interlayer film 15. Therefore, it is possible to reduce an influence in the formation of the dielectric film 12, for example, diffusion of oxidizing species in the dielectric film 12 to oxidize the plug 9.

Also in the method of manufacturing the capacitor 20 or the like, the interlayer film 15 may be caused to remain partially.

Eighth Embodiment

For example, the structure of the capacitor 10 in FIG. 2 can be applied to a plug. In the eighth embodiment, such a plug will be described.

In the semiconductor device 100 shown in FIG. 1 which has been described above, the via hole (or the hole) 85A is formed across the interlayer films 2, 8 and 3, and the plug 801 is provided in the via hole 85A. The plug 801 includes a plug body 81 which is formed of ruthenium, for example, and a ruthenium oxide film (or the conductor) 841 and the relationship between the plug body 81 and the ruthenium oxide film 841 corresponds to the relationship between the lower electrode 11 and the ruthenium oxide film 14 in the capacitor 10. hole 85A and is opened on the entry of the via hole 85A or the upper surface 3T of the interlayer film 3. A contact layer or a barrier metal layer may be provided as a part of the plug body 81 on the inner surface of the via hole 85A. The ruthenium oxide film 841 is formed on the plug body 81 to face the interlayer films 3, 8 and 2 through the plug body 81 in the via hole 85A, and furthermore, is also formed on the outside of the via hole 85A successively from the inside of the via hole 85A. Consequently, the ruthenium oxide film 841 closes the opening of the plug body 81.

The plug 801 can be manufactured by application of the method of manufacturing the capacitor 10 (see FIGS. 3 to 6). More specifically, the plug body 81 is first formed in the via hole 85A in the same manner as the lower electrode 11 and the exposed surface of the plug body 81 is then oxidized to form the ruthenium oxide film 841. While an opening appears after a CMP processing or a dry etch back processing due to a void also in the manufacture of the plug 801, the opening of the plug body 81 is closed by the formation of the ruthenium oxide film 841.

By such a manufacturing method, the ruthenium oxide film 841 is not provided in contact with the interlayer films 3, 8 and 2 on the outside of the via hole 85A, and furthermore, an upper surface 841T of the ruthenium oxide film 841 which is provided on the outside portion of the via hole 85A is formed on a higher level than that of the upper surface 3T of the interlayer film 3. When an electrical connection between the wirings 122 and 132 can be established, the plug body 81 and the ruthenium oxide film 841 do not need to completely fill in the via hole 85A.

According to such a plug 801, the ruthenium oxide film 841 is provided to close the opening of the plug body 81. Therefore, it is possible to prevent chemicals or the like from penetrating into the opening to erode the plug body 81 at the step to be executed semiconductor device 100 can be enhanced. Such an effect is also applicable to the capacitor 10 and the like.

By applying the lower electrode 11 and the ruthenium oxide film 24 in the capacitor 20 of FIG. 9 or the lower electrode 11 and the ruthenium silicide film 44 in the capacitor 40 of FIG. 17, it is also possible to form the same plug as the plug 801.

Since the ruthenium oxide film 841 is protruded beyond the upper surface 3T of the interlayer film 3 in the plug 801, drawbacks are caused in the formation of the wiring 132 or a contact in some cases. In consideration of such a respect, a shape of a plug 802 shown in a sectional view of FIG. 39 is desirable. More specifically, the plug 802 has such a structure that the ruthenium oxide film 841 in the plug 801 of FIG. 1 is replaced with a ruthenium oxide film 842. A shape of the ruthenium oxide film 842 is equivalent to a shape obtained by removing the portion of the ruthenium oxide film 841 which is provided on the outside of the via hole 85A in FIG. 1.

As shown in a sectional view of FIG. 40, it is possible to manufacture the plug 802 by removing a portion of the ruthenium oxide film 841 which is provided on the outside of the via hole 85A by a CMP method, for example, after the formation of the plug 801 (by flattening an exposed surface after the formation of the plug 801). After the formation of the plug 801, the opening of the plug body 81 is closed. Therefore, a void is not present in the vicinity of the entry of the opening or the vicinity of the upper surface 3T of the interlayer film 3. Consequently, it is possible to prevent an opening from being generated on the plug 802 by partially removing the ruthenium oxide film 841.

Since the plug 802 does not form a step with the upper surface 3T of the interlayer film 3, it is possible to avoid drawbacks in the formation of the wiring 132 and

By applying the lower electrode 11 and the ruthenium oxide film 24 in the capacitor 20 of FIG. 9 or the lower electrode 11 and the ruthenium silicide film 44 in the capacitor 40 of FIG. 17, it is also possible to form the same plug as the plug 802. In consideration of the fact that the plug body 81 of the plug 802 directly comes in contact with the wiring 132, it is also possible to apply the lower electrode 51 and the silicon nitride film 54 in the capacitor 50 of FIG. 23. In this case, since the silicon nitride film is an insulating material, the plug is formed by only the plug body.

The plug 802 can also be manufactured by the following manufacturing method. More specifically, as shown in a sectional view of FIG. 41, a conductive film 81P for the plug body 81 is formed, and a CMP processing or the like is not carried out but an oxidation treatment is then executed successively to form a ruthenium oxide film 84P. Thereafter, portions of both of the films 81P and 84P which are provided on the outside of the via hole 85A are removed by the CMP processing or the like. Thus, the interlayer film 3 is exposed (see FIG. 40).

In such a manufacturing method, it is necessary to form the ruthenium oxide film 81P to have an opening. The reason is that it is necessary to form the ruthenium oxide film 84P in the vicinity of the upper surface 3T of the interlayer film 3 to prevent a void from being present in the vicinity of the upper surface 3T in order that the plug 802 may have no opening after the CMP processing. In this case, also in the method of manufacturing the capacitor 10 described above, for example, the ruthenium film 11P (see FIG. 4) may be maintained to be open before the CMP processing as long as the opening 11A can be closed by the ruthenium oxide film 14. Such a respect is the same as in the methods of manufacturing the capacitor 20 and the like, and the plug 801.

Japanese Patent Application Laid-Open No. 2000-252441 has introduced a step is executed by deposition of an SrRuO₃ film and a CMP processing. On the other hand, for example, the ruthenium oxide film 841 shown in FIG. 1 according to the present application is formed by carrying out an oxidation treatment over the plug body 81. By a forming method, moreover, the SrRuO₃ in the same document is not protruded from a surface level of an interlayer film provided with the plug and has a different shape from the shape of the ruthenium oxide film 841 in FIG. 1 according to the present application.

Ninth Embodiment

In consideration of the plug 802 in FIG. 40 which has been described above, it is also possible to deform the capacitor 10 in FIG. 2 like a capacitor 90 shown in a sectional view of FIG. 42. The capacitor 90 can be applied to the semiconductor device 100 in FIG. 1 in place of the capacitor 10.

More specifically, the capacitor 90 is equivalent to a structure in which the portion of the ruthenium oxide film 14 that is provided on the outside of the opening 11A is removed in the capacitor 10, and has a ruthenium oxide film 94 in only the opening 11A. While other structures of the capacitor 90 are basically the same as those of the capacitor 10 in FIG. 2, a dielectric film 12 is provided in contact with an upper surface 11T of a lower electrode 11 (and faces the upper surface 11T at this time) in the capacitor 90 by application of the ruthenium oxide film 94 and is also provided in contact with a top surface (a surface arranged with the upper surface 11T) of the ruthenium oxide film 94.

By forming the ruthenium oxide film 14 as shown in FIG. 6 in the process for manufacturing the capacitor 10 and then removing the portion of the ruthenium oxide film 14 which is provided on the outside of the opening 11A by a CMP method or dry etch back, for example, it is possible to manufacture the capacitor 90. as those of the capacitor 10.

As described in the explanation of the capacitor 30 in FIG. 13, in the case in which the dielectric film 12 is formed of a crystalline material, for example, it is preferable that the foundation in the formation of the dielectric film 12 should be formed of a single material in order to obtain the homogeneous dielectric film 12. In the capacitor 90, the lower electrode 11 which is formed of ruthenium and the ruthenium oxide film 94 become the foundation of the dielectric film 12 and a rate of occupation of the lower electrode 11 in this foundation is higher than that in the capacitor 10. For this reason, in the case in which the ruthenium is suitable for the foundation, for example, in the case in which the dielectric film 12 is formed of tantalum oxide (Ta₂O₅), the capacitor 90 is more preferable.

The ruthenium oxide films 24 and 14 in FIGS. 9 and 37, the ruthenium silicide film 44 in FIG. 17 and the silicon nitride film 54 in FIG. 23 can also have the same shape as that of the ruthenium oxide film 94. Moreover, the (protruded) portion of the ruthenium oxide film 34 in FIG. 13 which is higher than the upper surface 11T of the lower electrode 11 can also be removed by dry etch back, for example.

Variant of First to Ninth Embodiments

For the lower electrode 11, the plug body 81 and the like, platinum group elements such as palladium (Pd) and rhodium (Rh) can also be used in addition to ruthenium and silicon. Moreover, (transparent) oxide semiconductors such as ITO (Indium Tin Oxide), GZO (Gallium doped Zinc Oxide), SrCu₂O₂ and CuInO₂ can also be applied.

Furthermore, the shape of the lower electrode 11 is not restricted to the pillar but may be a rectangular parallelepiped extended in a constant direction, for example, (in in the lower electrode 51, the plug 801 and the like.

While the invention has been shown and described in detail, the foregoing description is in all aspects illustrative and not restrictive. It is therefore understood that numerous modifications and variations can be devised without departing from the scope

What is claimed is:

1. A semiconductor device including a capacitor, comprising:
a lower electrode of said capacitor which has an upper surface and a side surface and has an opening on said upper surface;
an electric conductor or an insulator provided at least in the vicinity of an entry in said opening and containing a material of said lower electrode as a part of a composition;
a dielectric film of said capacitor which is provided to face said upper surface and said side surface of said lower electrode; and
an upper electrode of said capacitor which is provided to face said lower electrode through said dielectric film.

2. The semiconductor device according to claim 1, wherein said electric conductor or said insulator is also provided on said upper surface of said lower electrode successively from an inside of said opening.

3. The semiconductor device according to claim 2, wherein said electric conductor or said insulator is also provided on said side surface of said lower electrode successively from said upper surface of said lower electrode.

4. A semiconductor device including a capacitor, comprising:
a lower electrode of said capacitor which has an opening;
an insulator provided in a bottom portion of said opening without completely
a dielectric film of said capacitor which is provided on said insulator and said lower electrode without completely filling in said opening; and
an upper electrode of said capacitor which is provided on said dielectric film.

5. The semiconductor device according to claim 4, wherein said lower electrode has a roughened inner surface in said opening and/or has such a shape that said opening is gradually narrowed from an entry toward said bottom portion.

6. A semiconductor device including a plug, comprising:
an interlayer film having a hole;
a plug body provided in said hole with an opening in an entry of said hole; and
an electric conductor provided on an inside and outside of said hole to close said opening of said plug body and provided so as not to come in contact with said interlayer film, and containing a material of said plug body as a part of a composition,
said plug including said plug body and said electric conductor.

7. A method of manufacturing a semiconductor device, comprising the steps of:
(a) forming an interlayer film and opening said interlayer film to form a hole;
(b) forming a conductive film on said interlayer film to provide said conductive film in said hole;
(c) removing a portion of said conductive film which is provided on an outside of said hole, thereby exposing said interlayer film; and
(d) oxidizing, siliciding or nitriding an exposed surface of said conductive.

8. The method of manufacturing a semiconductor device according to claim 7, wherein said step (d) includes the step of forming said oxide film or said nitride film by plasma oxidation or plasma nitriding.

9. The method of manufacturing a semiconductor device according to claim 7, wherein said semiconductor device comprises a capacitor including, as a lower electrode, a portion of said conductive film which is provided in said hole, said manufacturing method further comprising the steps of:
(e) removing said interlayer film after said step (c) to expose a side surface of said lower electrode;
(f) forming a dielectric film of said capacitor to face an upper surface and said side surface of said lower electrode after said steps (d) and (e); and
(g) forming an upper electrode of said capacitor to face said lower electrode through said dielectric film.

10. The method of manufacturing a semiconductor device according to claim 9, wherein said step (e) is executed before said step (d).

11. The method of manufacturing a semiconductor device according to claim 9, wherein said step (e) includes the step of removing said interlayer film to leave a part of said interlayer film.

12. The method of manufacturing a semiconductor device according to claim
(h) removing a portion of said oxide film, said silicide film or said nitride film which is provided on an outside of said hole.

13. A method of manufacturing a semiconductor device including a capacitor, comprising the steps of:
(i) forming an interlayer film and opening said interlayer film to form a hole:
(j) forming a conductive film along an exposed surface in said hole;
(k) forming an insulator on said conductive film to fill in said hole;
(l) removing a portion of said conductive film which is provided on an outside of said hole to expose said interlayer film, thereby forming a lower electrode of said capacitor by said conductive film;
(m) removing said insulator to leave a part of said insulator in a bottom portion of an opening of said lower electrode corresponding to said hole;
(n) removing said interlayer film to expose said lower electrode;
(o) forming a dielectric film of said capacitor on said insulator and said lower electrode without completely filling in said opening after said steps (m) and (n); and
(p) forming an upper electrode of said capacitor on said dielectric film.

14. The method of manufacturing a semiconductor device according to claim 13, wherein said step (n) includes the step of removing said interlayer film to leave a part
